(19) United States
(12) Patent Application Publication
(10) Pub. No.: US 2015/0114826 A1
(43) Pub. Date: Apr. 30, 2015

(54) PVD APPARATUS FOR DIRECTIONAL MATERIAL DEPOSITION, METHODS AND WORKPIECE

(71) Applicant: OERLIKON ADVANCED TECHNOLOGIES AG, Balzers (LI)

(72) Inventor: Jurgen Weichart, Balzers (LI)

(73) Assignee: OERLIKON ADVANCED TECHNOLOGIES AG, Balzers (LI)

(21) Appl. No.: 14/405,294

(22) PCT Filed: Jun. 18, 2013
(86) PCT No.: PCT/EP2013/062637

§ 371 Date: Dec. 3, 2014

Related U.S. Application Data
(60) Provisional application No. 61/660,903, filed on Jun. 18, 2012.

(51) Int. Cl. C23C 14/34; H01J 37/34; C23C 14/35

(52) U.S. Cl. CPC C23C 14/3492; C23C 14/35; C23C 14/34; H01J 37/3423
USPC 204/192.12; 204/298.12

(57) ABSTRACT

Directional material deposition in physical vapor deposition (PVD) technology. In particular, the invention concerns PVD apparatus, which comprises a vacuum tight outer vessel accommodating a material source, at least two substrates arranged to define a substrate plane spaced apart from said material source, substrates facing the material source with a surface to be treated. The diameter of this material source is smaller, in particular significantly smaller, than the diameter of any of the substrates. Narrow angular distribution and a high level of uniformity is achieved at low substrate temperature.

### TECHNICAL FIELD OF THE INVENTION

The present invention is related to directional material deposition in physical vapor deposition (PVD) technology.

### BACKGROUND OF THE INVENTION

Directional material deposition is well known in semiconductor manufacturing industry, in particular for treating 3-D shaped surface structures. The directional material deposition results from a narrow angular distribution of particle flux, which is generated by using collimators, long distance sputtering or ionized PVD.

### SUMMARY OF THE INVENTION

The present invention has the objective to propose an improved PVD apparatus for directional material deposition, an improved cluster arrangement, an improved method of operating such a PVD apparatus, an improved method for manufacturing workpieces and an improved workpiece.

This objective is reached by a PVD apparatus comprising the features specified in claim 1. Further embodiments of the PVD apparatus, a cluster arrangement, a method for operating the PVD apparatus, a method for manufacturing workpieces and a workpiece are specified in the further claims.

The invention concerns a PVD apparatus for directional material deposition. This apparatus comprises:
a vacuum tight outer vessel accommodating a material source,
at least two substrates arranged to define a substrate plane spaced apart from said material source,
the substrates facing the material source with a surface to be treated.

The diameter of this material source is smaller, in particular significantly smaller, than the diameter of any of the substrates. This way a narrow angular distribution with a high level of uniformity and similar thickness distribution is achieved at a low substrate temperature.

Directional material deposition means that the flux of the material to be deposited is directed towards the substrate surface under a well-defined angle. This is particular useful for 3-D shaped surface structures such as holes, trenches or vias.

Throughout this description and the claims, the term “substrate plane” refers to a substantially plane-shaped treatment space. In case of four or more substrates, the substrate plain is defined by the average of the centres of the substrates. In case of three or less substrates, the substrate plain is defined by the centres of the substrates and in the case of two substrates, by the additional requirement that the substrate plane is perpendicular to the axis of the directional material deposition.

The term “diameter” as used throughout this description and the claims, for example as diameter of the material source or diameter of the substrate, refers to any kind of operational dimension, which is effectively used in the PVD processing. Thus, the term diameter may be the diameter of circular shapes but may also be a minimum, a maximum or an average diameter of an object, in particular of the material source or the substrate. For example, the diameter refers to an inner or an average or an outer diameter of a substantially polygon-shaped material source or substrate.

Surprisingly, the apparatus according to the invention achieves a narrow angular distribution over a short deposition distance and a high level of uniformity with a small target, i.e. a target with a small diameter. Further, the geometric dependency as known from long distance sputtering is reduced and a high level of similar or equal deposition thickness with respect to the substrate orientation is achieved.

Advantageously, the PVD apparatus according to the invention avoids the problems of collimators, i.e. disturbing particles. Further, a high energy input as known from ionized PVD processes is avoided, which is particular advantageous for lift-off processes using temperature sensitive polymer masks.

In an embodiment of the PVD apparatus according to the invention, the PVD apparatus is a sputtering apparatus, in particular a magnetron sputtering apparatus. This way a high film quality is achieved.

In a further embodiment of the PVD apparatus according to the invention, the material source is at least one of:
a single source,
a sputtering target, and
oriented substantially parallel to the substrate plane.

The sputtering target is also called simply “target” throughout this description.

In a further embodiment of the PVD apparatus according to the invention, the number of substrates is 2 or at least 3 or at least 4, in particular 3 or 4 and/or each of the centres of the substrates are arranged on a circle and equally spaced from each other, wherein the circle is located in the substrate plane.

In a further embodiment of the PVD apparatus according to the invention, the substrates are rotatable during the PVD processing, in particular in a planetary motion.

In a further embodiment of the PVD apparatus according to the invention, the substrates are tiltable to form a tilt angle with the substrate plane, wherein in particular the tilt angle is between 0-20°, further in particular between 0-15°.

In a further embodiment of the PVD apparatus according to the invention, the distance between the material source and the substrate plane is between 6-20 times larger than the diameter of the material source, in particular 6-10 times larger, further in particular 7-9 times larger.

In a further embodiment of the PVD apparatus according to the invention, the diameter of an individual substrate is between 2-6 larger than the diameter of the material source, in particular 3-6 times larger, further in particular 4-5 times larger.

In a further embodiment of the PVD apparatus according to the invention, the PVD apparatus comprises means for adjusting the distance between the material source and the substrate plane according to a predetermined value and/or the angle between the surface of the substrates and the substrate plane according to a predetermined value.

Further, the invention concerns a cluster arrangement of processing tools with a common central handling system allowing for the transport of substrates under vacuum between a load lock and multiple process stations, wherein one or more of the process stations comprise an apparatus according to any one of the previous embodiments.

Further, the invention concerns a cluster arrangement with at least one, in particular with two or at least two, of the apparatus according to any one of the previous apparatus embodiments, wherein in particular at least two of them are configured to treat an identical number of substrates.

Further, the invention concerns a method for directional material deposition by using a PVD apparatus with a material source. The method comprises the steps of:
proving at least two substrates in a vacuum tight outer vessel, the substrates defining a substrate plane spaced apart from said material source;
adjusting a distance between the material source and the substrate plane according to a predetermined value and/or an angle between the surface of the substrate and the substrate plane according to a predetermined value; and
treating the substrates by directional material deposition.

This way a narrow angular distribution with a high level of uniformity and similar thickness distribution is achieved at a low substrate temperature.

In a further embodiment of the previous method embodiment, the adjusting of the distance and/or angle comprises adjusting in dependency of at least one of:
the number of the substrates to be treated,
an outermost position of the substrates,
an emission profile of the material source, and
an angular distribution of the material to be deposited.

In a further embodiment of one of the previous method embodiments, the treating of the substrates comprises lift-off processing, which in particular is based on temperature sensitive masking.

Further, the invention concerns a method for manufacturing workpieces by using the PVD apparatus according to any one of the previous apparatus embodiments or one of the previous cluster arrangements or by performing the method according to any one of the previous method embodiments.

Further, the invention concerns a workpiece, which in particular comprises a 3-D shaped surface structure, further in particular a trench with an undercut, wherein the workpiece is manufactured according to the previous mentioned method for manufacturing.

It is expressly pointed out that any combination of the above-mentioned embodiments, or combinations of combinations, is subject to a further combination. Only those combinations are excluded that would result in a contradiction.

### BRIEF DESCRIPTION OF THE DRAWINGS

Below, the present invention is described in more detail by means of exemplary embodiments and the included simplified drawings. It is shown in:

FIG. 1 an arrangement schematically illustrating a sputtering apparatus according to the invention with a setup for 2 and 3 substrates;

FIG. 2 an emission profile of a 40 mm diameter sputtering source as used in the apparatus of FIG. 1;

FIG. 3 an angular distribution in the wafer centre;

FIG. 4 an angular distribution near the wafer edge (70 mm);

FIG. 5 a lift-off situation for a trench with 6° undercut in the wafer centre and 70 mm to the wafer edge;

FIG. 6 a lift-off situation for a trench with 13° undercut in the wafer centre, as well as off-centred 35 and 70 mm to the wafer edge;

FIG. 7 a dual-wafer setup mounted on a 4-sided cluster tool, process and load situation indicated; and

FIG. 8 two triple wafer modules mounted on a 4-sided cluster tool.

### BRIEF DESCRIPTION OF THE INVENTION

The described embodiments are meant as illustrating examples and shall not confine the invention.

### FIELD OF THE INVENTION

Directional sputtering is required in several applications in semiconductor manufacturing industry. Sputtering hereby addresses a well-known variant of physical vapour deposition (PVD) technology. Physical vapor deposition (PVD) is a general term used to describe any of a variety of methods to deposit thin films by the condensation of a vaporized form of a material onto a surface of a substrate (e.g. onto semiconductor wafers). The coating method involves purely physical processes such as high temperature vacuum evaporation or plasma sputter bombardment. Variants of PVD include Cathodic Arc Deposition, Electron beam physical vapor deposition, Evaporative deposition and Sputter deposition. Sputtering is commonly understood as a glow plasma discharge usually confined in a magnetic tunnel located on a surface of a target material to be deposited on a substrate. Directional sputtering means that the flux of sputtered material is directed towards the substrate surface under a well-defined angle, e.g. in order to allow access to holes, trenches or vias in the substrate. High integration of semiconductor devices creates the needs to treat such 3-D shaped surface structures.

In many applications such vias or trenches have to be seeded on their inner surfaces (vertical and horizontal ones) or even filled with sputtered material. In many cases it is required to achieve highest possible sidewall coverage as needed for subsequent electroplating steps. Other applications require as little sidewall deposition as possible. In the so called Lift-Off process a structured photo resist or other masking material is coated by a subsequent process and here a minimal sidewall deposition of the mask is required to enable the under-etch process and remove the deposited material on the top of the structured photo resist and leave the material on the substrate in the regions without photo resist. Typically for this application the thermal load has to be low due to involved organic materials.

### TECHNICAL BACKGROUND

Methods for directional sputtering are known in the Semiconductor technology and described in many articles and patents. Typical methods to generate a narrow angular distribution of the particle flux are collimators or the application of long distance sputtering. A very successful approach is the ionized PVD, where the sputtered the metal vapour is ionized by additional excitation (e.g. S. M. Rossnagel, J. Hopwood, J. Vac. Sci. Technol. B12, 449, 1994).

### DISADVANTAGES IN THE ART

The disadvantage of collimators is that these are situated directly in the deposition beam and collect a lot of material, which can uncontrollably delaminate from said collimators due to increasing film thickness and stress and cause particles.

The disadvantage of long throw sputtering in static arrangements is that high target-substrate-distances are required to have narrow angular distribution of the particle flux. For acceptable uniformities this means a large target diameter. Another downside of long throw sputtering is its strong geometric dependency causing different deposition thicknesses. This depends on whether the feature sidewall is directed towards or opposite to the symmetry axis of the arrangement.

In ionized PVD typically metal vapour is ionized, and the metal ions are—with the help of a negative bias potential—accelerated towards the substrate. The directionality is given by the electric field. In processes where sidewall coverage is required this ion etching is needed to remove material from the bottom of the feature and to deposit this on the sidewall. This is not wanted for the lift-off process. Another disadvantage of ionized PVD is the high energetic input on the substrate by the accelerated ions. In the case of lift-off processes with polymer masks the impacting ions may damage the mask material, so that its solution in solvents is disabled.

Lift-off processes are practiced by evaporation in batch tools currently. The disadvantage of batch tools is their high risk to lose a complete batch and their missing compatibility with single wafer in-line processing. The realization of automatic loading is much more difficult for systems of large batches. Finally in many cases also sputtering is preferred due to the superior film qualities against evaporated films.

### DESCRIPTION OF THE SOLUTION

The solution consists of a small source of material —preferably a sputtering target—facing a substrate or a set of several substrates at a large distance, so that a narrow angular distribution is achieved. Such a solution can preferably be realized by arranging a sputtering target in a plane above (i.e. vertically spaced apart) and parallel to a plane where one or more substrate (workpieces) are distributed. The substrates preferably are rotating in a planetary motion during the processing. The angular distribution depends on the distance between the target and the substrate plane (TS). In the substrate plane the substrates are arranged in a ring of densely packed circles where each circle consists of the substrate and some environment like a clamp or a shadow mask.

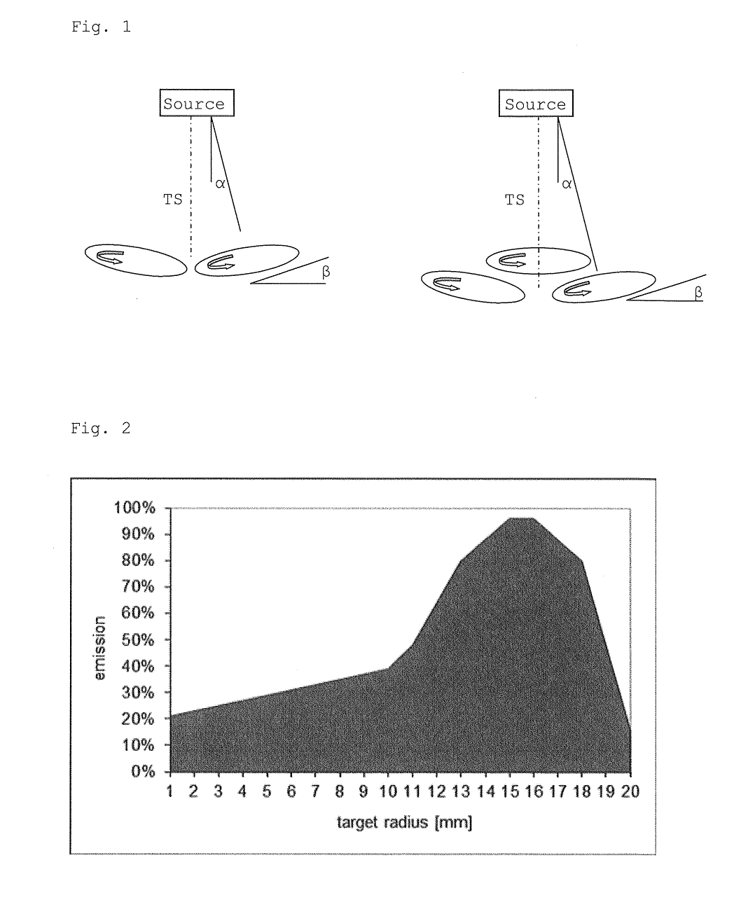

FIG. 1 shows an arrangement schematically illustrating a sputtering apparatus according to the invention with a basic setup for 2 and for 3 substrates. The source is positioned in a distance TS from the substrate plane in order to provide a certain angle to the outermost position of the substrate α. The substrates can be tilted in the substrate plane by an angle β to provide a good transfer factor and uniformity. To maintain the same angle α for more substrate a higher TS has to be used.

The following example is given for the lift-off application:

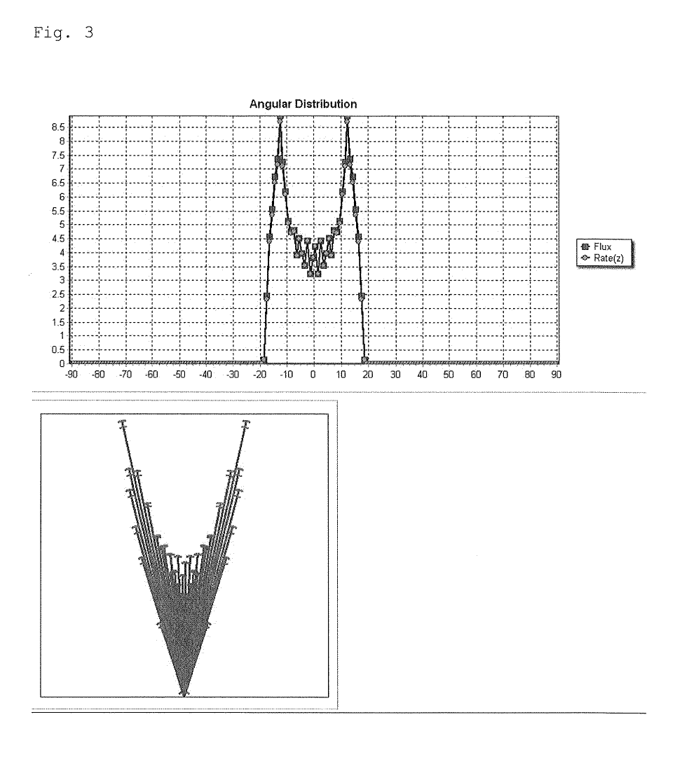

A set of 2 wafers with a diameter of 150 mm (each) are positioned in the substrate plane. A target of 40 mm diameter with an emission profile as plotted in FIG. 2 is mounted in a distance of 299 mm from a substrate plane, providing an angle β of 15° to the substrates with an offset of 80 mm between the target symmetry axis and the substrate symmetry axis. A 5 mm surrounding clearance is suitable to enable holder rings or masks. The 2 wafers are rotating in a planetary motion. Experiments have shown that the erosion of the target occurring over its lifetime does not negatively influence the uniformity of the layer deposition on the substrate.

FIG. 2 shows an emission profile of a 40 mm diameter sputtering source as used in the apparatus of FIG. 1.

The uniformity of the deposition is not only depending on the geometries, but also on the emission characteristics of the target material. With θ being the angle between the direction normal to the target the emission intensity as function of this angle θ can be described by:

I(θ)=I₀*(cos θ)^{c}

with the exponent c describing the emission characteristics. The uniformity is calculated for values of c of 0.6 and 1.

The results are summarized in Table 1, not only for the arrangement of 2, but also of 3 and 4 wafers. Table 1 shows that for an emission exponent c=1 (cosine) it is required to tilt the substrate in the substrate plane by 10° to achieve a good deposition uniformity on the substrate, whereas for c=0.6 no tilt is used. The table further shows that as soon as more substrates are arranged in the substrate plane the TS has to increase and the deposition is decreasing. Although very good uniformities can be achieved with more substrates the relative deposition rate per area (the outermost right column) of all substrates is decreasing by a factor 4 when 4 instead of 2 substrates are mounted. It has to be noted that the calculation has been performed without collisions in the gas phase. With collisions the decrease in rate by TS would be even worse.

TABLE 1

| substrate | | angle setpoint 15 deg | | | | wafer diam. 150 area 176.7 cm2 | | | | |
|---|---|---|---|---|---|---|---|---|---|---|
| diameter 160 | | | | | Uniformity | Uniformity | dep. rate | dep. rate | total area | rel. dep. |
| n | r | TSD | c | β | for c:1 | for c:0.6 | for c:1 | for c:0.6 | [cm2] | per area |
| 2 | 80.0 | 298.6 | 1.0 | 10.4 | 0.20% | | 0.00073 | | 353 | 100% |
| 2 | | | 0.6 | 0 | | 1.25% | | 0.00107 | 353 | 147% |
| 3 | 92.4 | 344.8 | 1.0 | 10.3 | 0.03% | | 0.00047 | | 530 | 43% |
| 3 | | | 0.6 | 0 | | 0.92% | | 0.00081 | 530 | 74% |
| 4 | 113.1 | 422.2 | 1.0 | 10.1 | 0.06% | | 0.00033 | | 707 | 23% |
| 4 | | | 0.6 | 0 | | 0.61% | | 0.00054 | 707 | 37% |

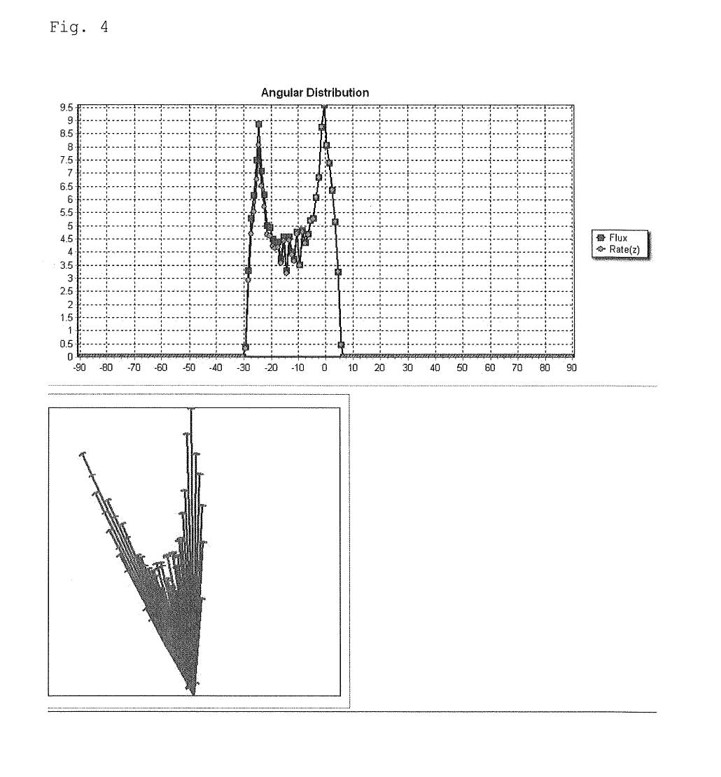

Table 1 shows geometries, uniformities, rates and relative deposition rate per area for setups with 2, 3 and 4 substrates, calculated for emission exponent c=1 and c=0.6 The angular distribution of material sputtered from the 40 mm target has been calculated for the situation of the 2 substrates. FIG. 3 shows an angular distribution of the sputtered flux reaching the wafer centre of one of the two rotating wafers. (0° means normal to the substrate surface) The lower of the two figures shows the same situation in a polar diagram.

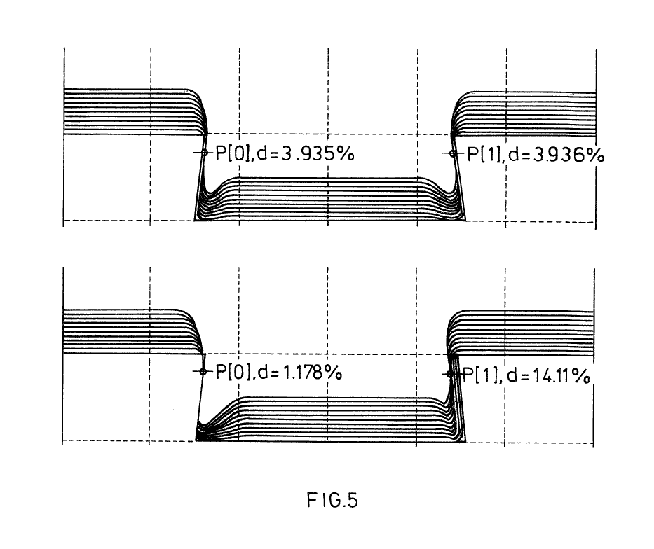

FIG. 4 shows an angular distribution of the sputtered flux reaching the edge in 70 mm distance from the wafer centre of one of the two rotating wafers is plotted. Again, the lower drawing shows the same situation in a polar diagram.

FIG. 5 shows a lift-off situation for a trench with 6° undercut in the wafer centre and 70 mm to the wafer edge.

On the substrate side trenches of 1 μm depth and 3 μm width with tangential orientation (i.e. circles or spirals) are used on the substrate. The trenches consist of a photo resist manufactured with a certain undercut (see FIG. 5) to facilitate the lift-off process. Two cases with trench undercut of 6° and 13° are demonstrated. The trenches are in the wafer centre, 35 mm from the centre and 70 mm from the centre. A film of 0.5 μm thickness is deposited.

In the case of 6° undercut the sidewall of the trench in the wafer centre collects a relative thickness of 3.9% to the top thickness. For the trench being 70 mm off-centred the inner side has a sidewall coverage of 1.2% and the outer side has a sidewall coverage of 14% (FIG. 5).

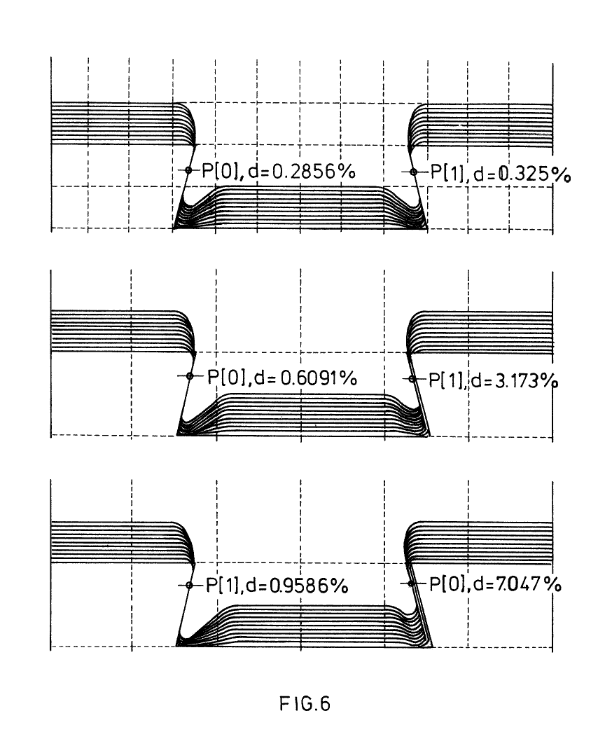

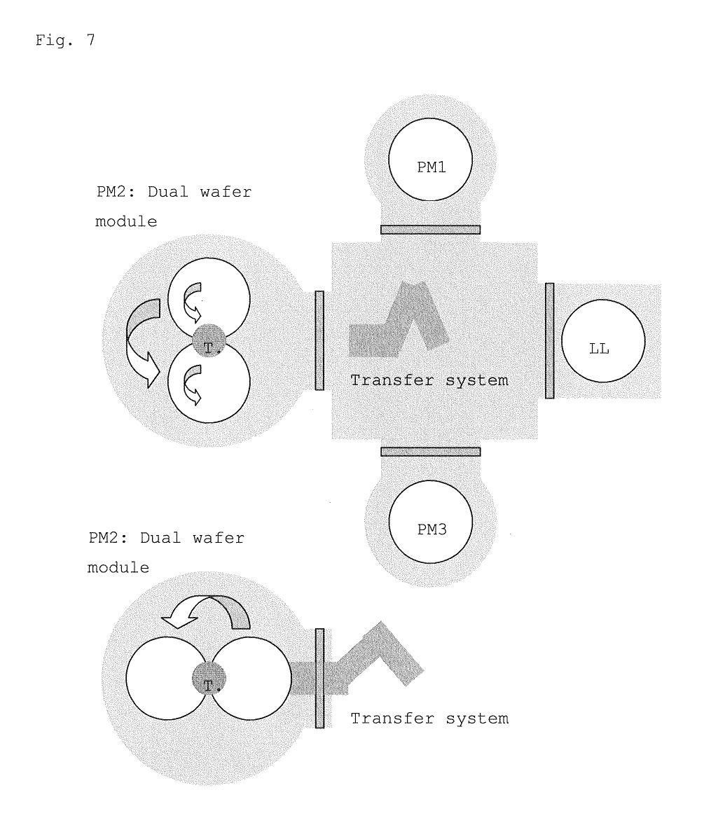

FIG. 6 shows a lift-off situation for a trench with 13° undercut in the wafer centre, as well as off-centred 35 and 70 mm to the wafer edge.

In the case of 13° undercut the sidewall of the trench in the wafer centre collects a relative thickness of 0.3% to the top thickness. For the trench being 35° off-centred the inner side has a sidewall coverage of 0.61% and the outer side has a sidewall coverage of 3.2%. For the trench being 70 mm off-centred the inner side has a sidewall coverage of 0.96% and the outer side has a sidewall coverage of 7% (FIG. 6). The latter is expected to be thin enough to enable the lift-off process.

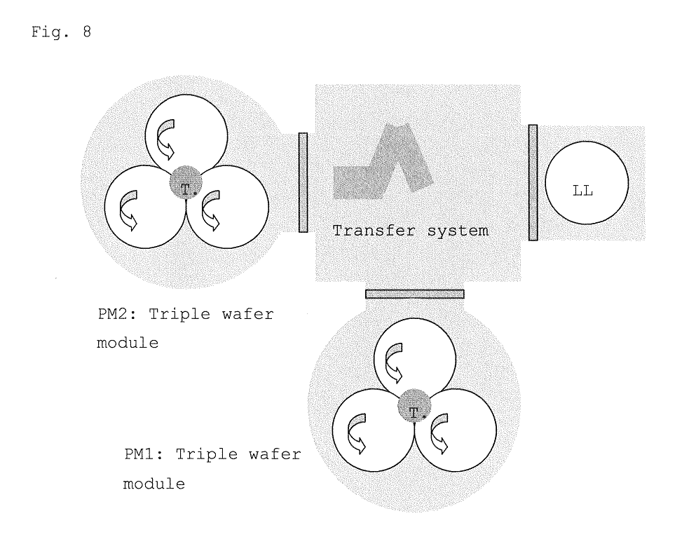

FIG. 7 shows an implementation of a dual-wafer setup in a modern cluster tool. Here a 4-sided robot handler is used with a load lock station (LL) on one port and process modules PM1 and PM3 for regular single wafer processing. The process modules are locked from the handling chamber by gate valves. PM2 contains the dual-wafer setup with the target T. In the lower part of the sketch the loading arm of the transfer system is extended into PM2 to illustrate the loading. A rotating drive for the substrate plane has to position the wafer 1 and 2 of the dual-wafer setup to the load port to enable loading and unloading. By a 180° rotation both wafers are accessible. The wafers are situated on retractable pins in the substrate plane setup allowing lifting the wafer so that the handler can pick it up.

FIG. 8 shows two triple wafer modules mounted on a 4-sided cluster tool. The combination of single and multi wafer modules may be problematic for the flow of material in production, but solutions like working with two single wafer modules in a “branch-mode”, like PM 1 and 3 in FIG. 7, are possible. In the case of the lift-off process only this and no other processes may be run on a deposition tool. Here a possible configuration is the use of two triple wafer modules mounted on a 4-sided cluster tool as sketched in FIG. 8. Here module PM1 may be loading substrates from the load lock by the transfer system while module PM2 is processing wafers, and vice versa.

### SUMMARY

The invention addresses:

A magnetron sputtering arrangement comprising:
a vacuum tight outer vessel accommodating a single sputtering (PVD) source,
at least two substrates arranged in a plane (“substrate plane”) spaced apart from said sputtering sources (“target-substrate distance”),
said substrates facing the source with a surface to be treated by the sputtering source
   wherein the target diameter is significantly smaller than any of the substrates' diameter.

Said sputtering arrangement, wherein:
The number of substrates is 2, 3 or 4, wherein the centres of the substrates are arranged on a circle equally spaced from each other, said circle being located in the substrate plane
The substrates being rotatable during sputter treatment
The substrates being tiltable to form an angle beta with the substrate plane

In one example, the invention involves the sputtering arrangement as described above, wherein
The target-substrate distance is between 6-20 times larger than the target diameter, preferably 6-10 times larger and even more preferably 7-9 times larger.
The diameter of an individual substrate is between 2-6, preferably 3-6 times larger than the target diameter, even more preferably 4-5 times larger.

In one example, the invention involves the sputtering arrangement as described above with beta between 0-20°, preferably 0-15°.

In one example, the invention involves a cluster arrangement of processing tools with a common central handling system allowing for the transport of substrates under vacuum between a load lock (access from environment under atmospheric conditions) and various process stations, wherein one or more process stations comprise a sputtering arrangement as described above.

1. A PVD apparatus for directional material deposition, comprising:
a vacuum tight outer vessel accommodating a material source,
at least two substrates arranged to define a substrate plane spaced apart from said material source,
said substrates facing the material source with a surface to be treated,
wherein the diameter of the material source is smaller, in particular significantly smaller, than the diameter of any of the substrates.

2. The apparatus according to claim 1, wherein the PVD apparatus is a sputtering apparatus, in particular a magnetron sputtering apparatus.

3. The apparatus according to claim 1, wherein the material source is at least one of:
a single source,
a sputtering target, and
oriented substantially parallel to the substrate plane.

4. The apparatus according to claim 1, wherein the number of substrates is 2 or at least 3 or at least 4, in particular 3 or 4 and/or each of the centres of the substrates are arranged on a circle and equally spaced from each other, said circle being located in the substrate plane.

5. The apparatus according to claim 1, wherein the substrates are rotatable during PVD processing, in particular in a planetary motion.

6. The apparatus according to claim 1, wherein the substrates are tiltable to form a tilt angle with the substrate plane, wherein in particular the tilt angle is between 0-20°, further in particular between 0-15°.

7. The apparatus according to claim 1, wherein the distance between the material source and the substrate plane is between 6-20 times larger than the diameter of the material source, in particular 6-10 times larger, further in particular 7-9 times larger.

8. The apparatus according to claim 1, wherein the diameter of an individual substrate is between 2-6 larger than the diameter of the material source, in particular 3-6 times larger, further in particular 4-5 times larger.

9. The apparatus according to claim 1, wherein the PVD apparatus comprises means for adjusting the distance between the material source and the substrate plane according to a predetermined value and/or the angle between the surface of the substrates and the substrate plane according to a predetermined value.

10. A cluster arrangement of processing tools with a common central handling system allowing for the transport of substrates under vacuum between a load lock and multiple process stations, wherein one or more of the process stations comprise an apparatus according to claim 1.

11. A cluster arrangement with at least one, in particular with two or at least two, of the apparatus according to claim 1, wherein in particular at least two of them are configured to treat an identical number of substrates.

12. A method for directional material deposition by using a PVD apparatus with a material source, the method comprising the steps of:
proving at least two substrates in a vacuum tight outer vessel, the substrates defining a substrate plane spaced apart from said material source;
adjusting a distance between the material source and the substrate plane according to a predetermined value and/or an angle between the surface of the substrates and the substrate plane according to a predetermined value; and
treating the substrates by directional material deposition.

13. A method according to claim 12, wherein the adjusting of the distance and/or angle comprises adjusting in dependency of at least one of:
the number of the substrates to be treated,
an outermost position of the substrates,
an emission profile of the material source, and
an angular distribution of the material to be deposited.

14. The method according to claim 12, wherein the treating of the substrates comprises lift-off processing, which in particular is based on temperature sensitive masking.

15. A method for manufacturing workpieces by using the PVD apparatus according to claim 1.

16. A workpiece, which in particular comprises a 3-D shaped surface structure, further in particular a trench with an undercut, wherein the workpiece is manufactured according to the method of claim 1.

17. A method for manufacturing workpieces by using the cluster arrangement according to claim 10.

18. A method for manufacturing workpieces by performing the method according to claim 12.
